(19) United States
(12) Patent Application Publication
(10) Pub. No.: US 2009/0303673 A1
(43) Pub. Date: Dec. 10, 2009

(54) Protective enclosure for an electronic device

(76) Inventor: Mark Holzhausen, Palm Beach Gardens, FL (US)

Correspondence Address: MCHALE & SLAVIN, P.A., 2855 PGA BLVD, PALM BEACH GARDENS, FL, 33410, US

(21) Appl. No.: 12/135,776

(22) Filed: Jun. 9, 2008

(51) Int. Cl. H05K 7/00

(52) U.S. Cl. 361/679.17; 361/679.23

(57) ABSTRACT

The purpose of this invention is to provide protective enclosure for an electronic device including: front cover, back cover, and a membrane. The front cover has a plurality of independent zones, each zone having a front surface area greater than the front surface area of an electronic device's function keys. The front cover inner face having protrusions corresponding to each zone and in alignment with the electronic device's function keys. A membrane, with a central protrusion configured to overlay the front cover, includes indicia thereon corresponding to an electronic device's function keys. The back cover includes a pair of clasps and fastener for attaching to a body or object. Front and back cover are configured to sealing mate and define an interior housing for an electronic device. Exertion of a downward force on indicia of the membrane causes deflection upon a corresponding zone and protrusion and activating the corresponding electronic device's function key.

### FIELD OF THE INVENTION

This invention relates generally to electronic devices, and more particularly, to a protective enclosure for an electronic device having an interactive generally flat panel control.

### BACKGROUND OF THE INVENTION

A media player is an electronic device that stores, organizes, and plays audio files. Commonly used media players include the IPod®, IPod Nano®, IPod Shuffle®, and Zune®. Media players are generally compact, sleek, and slim. Generally, media players have an interactive generally flat panel control. The interactive control may consist of a touchpad, pushbuttons and/or a screen display to perform different functions; because of the slim and compact style of most media players most touchpads or pushbuttons on the interface are reduced in size. Thus the depression of the media player's touchpad or pushbutton becomes more difficult. It is not uncommon for a user to inadvertently press two functions at once on the media player's interface due to the smaller touchpad or pushbutton.

Furthermore, the use of media players has increasingly become popular during events such as cross-training, weight-training, running, snow sports, or the like. These activities require tremendous amounts of concentration, time, and effort and thus it is awkward, difficult, inconvenient, and troublesome for a user to have to waste time fiddling with a media player's touchpad or pushbuttons while performing these activities. In addition, if these activities require bulky gloves, such as when skiing, then having to press a function key on the media player interface becomes a daunting task, for the surface area of glove finger is almost as large as the media player's entire interface. Thus the user must either take off his/her gloves to select a function key or be fortunate enough to not have selected the wrong function key. Even without the use of gloves, the surface area of a user's finger may occasionally be too large to press down on just one function key. In the case where the user's finger is slight it is still possible to encounter instances where the user is intending to press one function key and inadvertently depresses another because of an un-steady hand. Ironically, one of the reasons for the purchase of a media player, its small configuration, becomes the source of the user's problem; thus an enlarged user interface that would allow for more efficiency for the user in depressing the touchpad or pushbuttons is what the prior art calls for.

Additionally, media players are being widely used by individuals on the go. The transient use of media players has spurred the development of various carrying devices for attachment of the media player to an object. Carrying devices generally protect a media player from the environment and allow for attachment of a media player to the body or objects, such as an arm or belt. Furthermore, most carrying cases contain a feature allowing user interplay with the media player, for example having a central opening thereabout the case where the interactive control panel would be located for user manipulation of the function keys. The drawback to these cases is the environmental exposure the device is subjected to because of the central opening, thus eliminating one of the primary functions for which the carrying case seeks to protect against. More sophisticated carrying cases have included a membrane on that central opening that allows a user to perform functions on the media player without having to expose the device to the environment or remove the media player from the carrying case. While these cases protect from exposure to environmental elements, they have not improved upon an existing problem, the smaller function keys on the media player's interface.

Alleviating the existing problem of a small interface on a media player as well as protecting the media player from the environment and enabling attachment to an object is what is needed in the art. As a consequence of these aforementioned problems, it is an objective of the present invention to provide a water and moisture resistant container with enlarged user interface for a media player that attaches to a body part or object.

### DESCRIPTION OF THE PRIOR ART

The prior art discloses numerous touchpad enlargers for use on telephones as well as protective casings for portable digital devices.

U.S. Publication No. 2007/0139873 A1, to Brandenburg, U.S. Pat. No. 7,230,823 B2, to Richardson et al, U.S. Pat. No. 7,180,735 B2, to Thomas et al., U.S. Pat. No. 7,158,376 B2, to Richardson et al., U.S. Pat. No. 6,995,976 B2, to Richardson, and U.S. Pat. No. 6,646,846, to Richardson discloses a protective enclosure for touch screen devices. The enclosure includes a protective membrane adapted thereto, and membrane overlaying the touch screen of an electronic device to allow the user to use the touch screen with no shortcomings.

U.S. Patent No. 2007/0215663, to Chongson et al. discloses a water resistant case for electronic devices allowing a user to protect the device from damage by water, abrasion and or impact. The case provides a tactile sensitive window for viewing a screen and manipulating the controls of the device. Other accessory components allow securing the case to a person or vehicle.

U.S. Publication No. 2004/0204204 A1, to Brilliant discloses a phone handset case or cover, with a membrane element on the case face positioned over the operating keys of the phone handset. The membrane element provides enlarged indicia corresponding positionally with the operating indicia of the operating keys of the phone. The membrane element flexibility enables tactile location of each of the operating keys from an outfacing surface of the membrane element. Press down of the membrane element contacts operating keys of the phone. The elasticity of the membrane and not a lever returns the membrane to its original position.

U.S. Pat. No. 5,802,171, to Deutsch discloses a keypad enlarger kit that adapts to be mounted to a front panel of a conventional pay telephone in a manner so that large pushbuttons over lay the telephone keypad. The press down of a large pushbutton causes press down of the corresponding telephone pushbutton. The each large pushbutton surface area is greater than the front surface area of the telephone pushbutton.

U.S. Pat. No. 4,529,849, to Kamei et al. discloses a push-button switch affording smaller depressing force unto a stroke converting mechanism. The stroke converting mechanism includes a first arm and second arm. At the end of the first arm there is a semi circular bend at the end of which begins the second arm. The press down of the push button engages the first arm which in turn engages the second arm to make break contact on the circuit. The resiliency of the stroke mechanism places the push-button to its original position.

While these prior arts may be suitable for the particular purpose to which they address, these prior arts would not be suitable for the purposes of the present invention as heretofore described. It is desirable to provide a water and moisture resistant container with enlarged user interface for a media player.

### SUMMARY OF THE INVENTION

The objective of this invention is to provide a protective enclosure for an electronic device having an interactive generally flat panel control, including: a front cover, back cover, an interior housing, and a membrane. The front cover having sidewalls, a first continuous edge portion, a center opening, an inner face, and an outer face. The front cover having a center opening and a plurality of independently sectioned flexible zones, each independently sectioned flexible zone having a front surface area greater than front surface area of an electronic device's function keys. The front cover outer face including a continuous channel thereabout the perimeter. The front cover inner face has protrusions on each zone and in alignment with the electronic device's function keys. A membrane is constructed to overlay the channel on the front cover outer face. The membrane is configured to overlay the independently sectioned flexible zones and the center opening on the front cover. The membrane also includes indicia corresponding to an electronic device's function keys, as well as a central protrusion on each side of membrane corresponding to electronic device's center function key. A back cover, having sidewalls, a second continuous edge portion, and a pair of clasps having an attachable securing mechanism such as a Velcro strap for attaching to clothing, body parts, or vehicles. Front cover first continuous edge portion and back cover second continuous edge portion are configured to sealing mate and defining an interior housing for electronic device. Exertion of a downward force on a particular indicia of the membrane causes deflection upon a corresponding independent zone and protrusion and activates the corresponding electronic device's function key in alignment with protrusion; and depression of the central protrusion on the membrane causes depression of the electronic device's center function key. The front and back cover have an enclosure means to securely adapt each cover to the other to create a water and moisture resistant environment for an electronic device such as an media player. Additionally, disposed on the front cover is a small aperture to allow the entry of plug-in components and plug-in component is used in conjunction with aperture to resist the entry of water or moisture. The protective enclosure allows for easy operation of the electronic device's function keys while enclosed in a water and moisture resistant environment. Furthermore, the enlarged indicia on the membrane and greater surface area on the independently sectioned zones allows for greater error in pressing down on the corresponding function key of the electronic device.

Accordingly, it is an objective of the present invention to provide a container with a larger actuator interface for a media player capable of providing a water and moisture resistant enclosure with an enlarged interface to manipulate a media player's function keys while the media player is in a protective environment.

It is a further objective of the present invention to provide a container with a larger actuator interface for a media player increasing the surface contact area of a media player's function keys while in a protective environment.

It is an additional objective of the present invention to provide a container with a larger actuator interface for a media player with a membrane that is replaceable and may have decorative features thereon.

It is another objective of the present invention to provide a container with a larger actuator interface for a media player made of a synthetic material capable of resisting water and moisture as well as provide strength, dampening, and resiliency.

It is yet another objective of the present invention to provide a container with a larger actuator interface for a media player capable of performing most all the functions a media player can outside an enclosure as the media player can while inside an enclosure; as well as alleviate frustration with the common error of depressing simultaneous function keys.

It is another further objective of the present invention to provide a container with a larger actuator interface for a media player that includes an aperture to allow a plug-in component to be connected to the media device while in the container.

It is a further objective of the present invention to provide a container with a larger actuator interface for a media player capable of holding an excess wire from the plug-in component within the container so as to not tangle or get caught with foreign object as well as to not annoy or get in the way of the user.

It is a further objective of the present invention to provide a container with a larger actuator interface for a media player that includes securing straps to attach to a body part or object.

It is a further objective of the present invention to provide a container with a larger actuator interface for a media player that includes an engaging mechanism to turn on and off the media player from outside the protective enclosure.

It is a further objective of the present invention to provide a container with a larger actuator interface for a media player that accommodates an individual with physical or visual limitations, such as depleted vision, visually impairment, or an unsteady hand.

It is a further objective of the present invention to provide a container with a larger actuator interface for a media player that allows individuals wearing gloves or anyone else greater leeway in the surface contact area of a media player's function key.

It is a further objective of the present invention to provide a container with a larger actuator interface for a media player designed to securely attach to a an object, if the object is an arm the invention is ergonomically constructed for a comfortable fit.

Other objectives and advantages of this invention will become apparent from the following description taken in conjunction with any accompanying drawings wherein are set forth, by way of illustration and example, certain embodiments of this invention. Any drawings contained herein constitute a part of this specification and include exemplary embodiments of the present invention and illustrate various objects and features thereof.

### BRIEF DESCRIPTION OF THE FIGURES

FIG. 1 is a perspective view of an electronic device in accordance with the instant invention.

FIG. 2 is a perspective view of the enclosure in an open position.

FIG. 3 is a perspective view of the enclosure in a closed position.

FIG. 4 is a cross-sectional view of the first and second continuous edge portions of the enclosure.

FIG. 5 is perspective top view of a membrane that is to be secured to the enclosure.

FIG. 6 is perspective top view of a membrane as shown in FIG. 5 with a decorative pattern.

FIG. 7 is a cross-sectional side view of a mechanical actuator mechanism mounted on the enclosure to control the ON/OFF feature of an electronic device.

### DETAILED DESCRIPTION OF THE INVENTION

Detailed embodiments of the instant invention are disclosed herein, however, it is to be understood that the disclosed embodiments are merely exemplary of the invention, which may be embodied in various forms. Therefore, specific functional and structural details disclosed herein are not to be interpreted as limiting, but merely as a basis for the claims and as a representation basis for teaching one skilled in the art to variously employ the present invention in virtually any appropriately detailed structure.

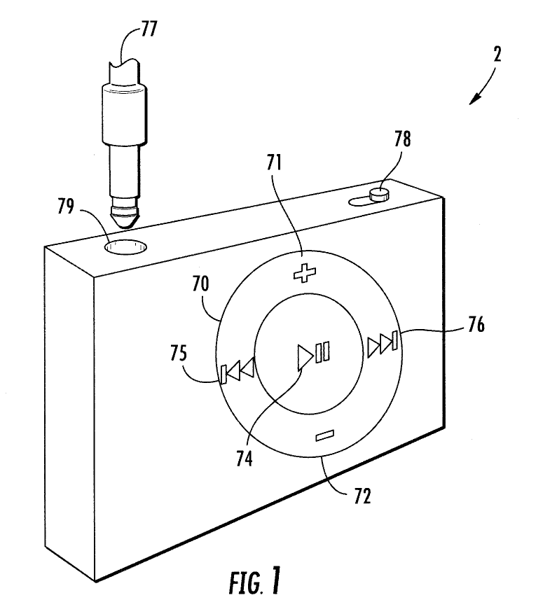

Referring now to FIGS. 1-6, wherein like elements are numbered consistently throughout, FIG. 1 illustrates an electronic device 2, commonly referred to as a media player or MP3 player and more specifically as an IPod Shuffle® 2^{nd} generation. The electronic device 2 is rectilinearly shaped, having straight lines; but it is contemplated that the electronic device 2 be curvilinear, which has curved lines. The electronic device 2 having function keys 70 consisting of an increase in volume 71, decrease in volume 72, play/pause 74, rewind 75, and fast forward 76. The function keys 70 operate as pushbuttons, which work as input devices that activate an electric circuit when pushed. The play 73 and pause 74 function keys are located on the center of the electronic device 2. The increase in volume 71 and decrease in volume 72 function keys are diametrically opposed from one another as are the rewind 75 and fast forward 76 function keys. Located on the sidewalls of the electronic device 2 is an ON/OFF switch 78 and an input for a plug-in component 79. Although FIG. 1 depicts an IPod Shuffle® 2^{nd} generation, the present invention has contemplated use for an IPod Shuffle® 1^{st} generation, IPod Nano®, or any other media player having similar interface configuration. This similar interface includes at least one set of diametrically opposed functions keys and including but not necessary a function key at the center of the diametrically opposed function keys.

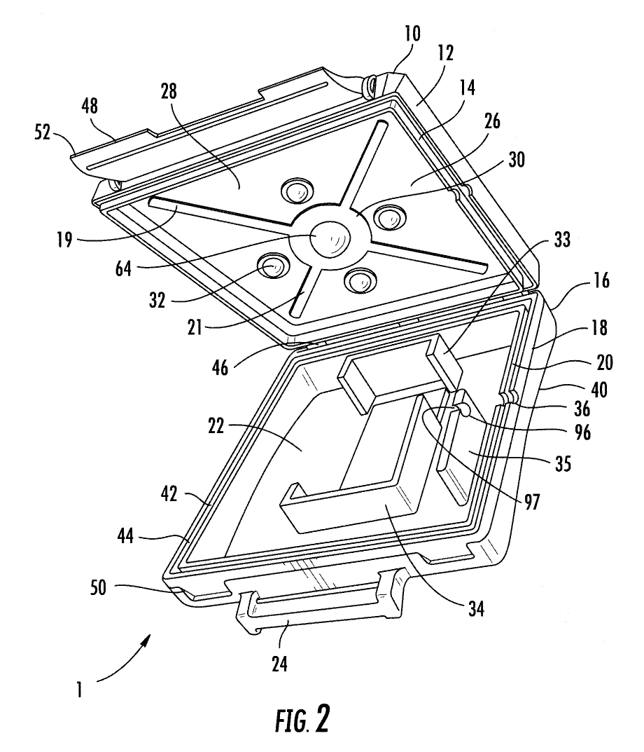

FIG. 2 illustrates a preferred embodiment of a protective enclosure for an electronic device having an interactive generally flat panel control according to the present invention, generally referenced herein as protective enclosure 1. As shown, the protective enclosure 1 is in an open position. The protective enclosure 1 is constructed of a synthetic material such as thermoplastic, preferably ABS plastic but not limited to this material selection. The protective enclosure 1 comprises of a front cover 10 having front cover sidewalls 12 and a first continuous edge 14 about the sidewalls 12; and a back cover 16 having back cover sidewalls 18 and a second continuous edge 20 about the sidewalls 18. The front and back cover sidewalls, 12 and 18, each having four sides when the front cover 10 and back cover 16 are rectangular shaped; but the sidewalls may be one sidewall if the front cover 10 and back cover 16 are circular shaped. The front cover 10 and back cover 16 are attached together by a hinge 46 located on adjacent front cover and back cover sidewalls, 12 and 18, respectively. When front cover 10 and back cover 16 are pivotally attached about the hinge 46 it defines an interior housing 22 that stores an electronic device 2.

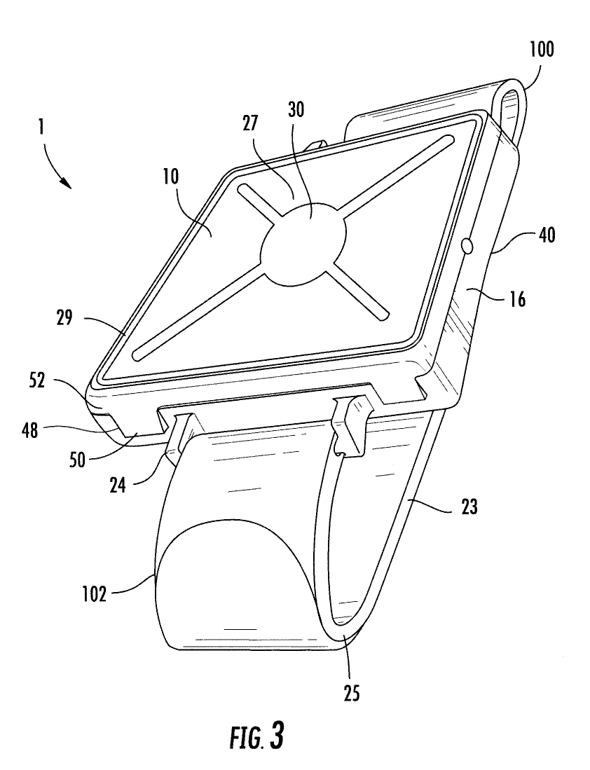

On the front cover 10 is a center opening 30 having a radius at least the size of the play/pause 74 function key. Front cover 10 includes a plurality of independently sectioned flexible zones 28; the preferred embodiment shows four independently sectioned flexible zones 28. The four independently sectioned zones 28 are formed by two slits orthogonally oriented with respect to each other. The slits 19 and 21 are defined as a straight opening therethrough the front cover 10. Each independently sectioned flexible zone 28 deflects about a pivot line located at the intersection of the front cover 10 and the corresponding front cover sidewall 12. The surface area of each independently sectioned flexible zone 28 is larger than the surface area of each electronic device's function key 70. The front cover 10 has an inner face 26 and outer face 27 (shown in FIG. 3). On the front cover inner face 26 is located a plurality of protrusions 32 on each independently sectioned flexible zone 28; the preferred embodiment shows four protrusions 32 corresponding to the four independently sectioned flexible zones 28. Each protrusion 32 is in alignment with a separate function key 70, such as increase in volume 71, decrease in volume 72, rewind 75, and fast forward 76.

The back cover 16 includes a pair of clasps 24 disposed on opposing sides of the back cover sidewalls 18. The back cover is ergonomically configured 40 to comfortably fit around an arm of an average human being; but optionally may have a flat surface. Within the interior housing 22 and attached to the back cover 16 are at least two holding members 33 and 34. The holding members 33 and 34 position the electronic device 2 in the center of the interior housing 22, so that the electronic device's function keys 70 are in alignment with the protrusions 32 on the independently sectioned zones 28 and the central protrusion 64 on the membrane backside 58. The holding members 33 and 34 are constructed to hold an electronic device 2 in place. The holding members 33 and 34 each have at least two walls to contain the electronic device 2. Two right angled walls on the top holding member 33 and two opposite right angled walls on the bottom holding member 34 would be sufficient to hold an electronic device 2 because the electronic device 2 is rectilinear. However, more than two walls on each holding member are suitable. Optionally the holding members 33 and 34 may be interchangeable so that a different electronic device 2 of a different shape such as curvilinear may be disposed with the center of the interior housing 22 of the protective enclosure 1.

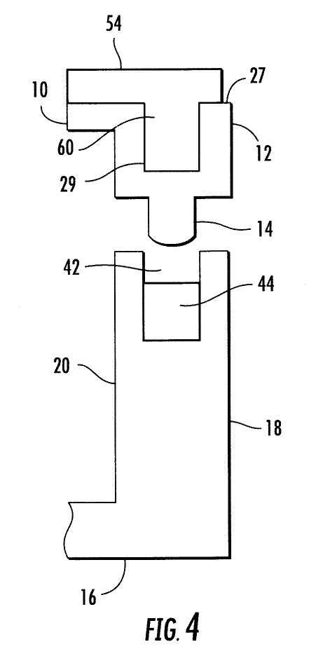

The back cover second continuous edge 20 has a groove 42. Within the groove 42 is a rubber seal 44, although the seal 44 may be of another material capable of providing a sealing mate between first continuous edge 14 and second continuous edge 20 (more prominently shown in FIG. 4).

Additionally, about the front cover sidewall 12, or back cover sidewall 18, or both is located an aperture 36. The aperture 36 allows for entry of a plug-in component 77. When the plug-in component 77 is used in cooperation with the aperture 36 they resist the entry of water and moisture into the interior housing 22. The aperture 36 is sized to snuggly fit the plug-in component's wire 77. The plug-in component 77 is inserted into the plug-in input 79 on the electronic device 2 to allow for proper operation. The plug-in component's wire 77 normally becomes an annoyance to a user, thus an alternative embodiment contemplates a cleat assembly 35 for wrapping excess wire 77 along thereof. The cleat assembly 35 comprises of a cleat 97 and a small notch 96. The cleat assembly 35 is to be located on the back cover 16 within the interior housing 22 at some distance between the aperture 36 and the holding member 34 and offset the back cover sidewall 18. The small notch 96 holds the plug-in component's wire 77. The wire 77 is wrapped about the cleat 97 and followed through within the notch 96 for holding the wire in place. The wire 77 is then passed through the aperture 36 for use by a user.

Opposite the hinge 46, on the front and back cover sidewalls 12 and 18 is located a locking mechanism 48. The locking mechanism 48 comprises of at least one hinge member 52 on the front cover sidewall 12 and a latching member 50 on back cover sidewall 18. In the closed position 6, the hinge member 52 fastens the front cover 10 to the back cover 16 when locked onto the latching member 50 (as shown in FIG. 3). In the open position, the hinge member 52 is no longer fastened to the latching member 50; and front and back cover, 10 and 16, respectively, are free to pivot about the hinge 46.

FIG. 3 illustrates the preferred embodiment of the protective enclosure 1 in a closed position. In the closed position, the hinge member 52 fastens the front cover 10 to the back cover 16 when locked onto the latching member 50. Once the protective enclosure 1 is in the closed position it is capable of resisting water and moisture, the entry of which may destroy an electronic device 2. Additionally, the front cover outer face 27 contains at least one continuous channel 29 about the perimeter thereof. The continuous channel 29 is defined as two parallel sidewalls joined by a bottom wall; where the depth of the channel 29 is not greater than the thickness of the front cover 10.

A securing mechanism 23 comprising of a hook and loop fastener, such as a Velcro® strap, 25 integrated with a pair of clasps 24 is shown. The Velcro® strap 25 has a fixed end 100 attached to one clasp 24; and a removably secure end 102 attached to the other clasp 24. Although Velcro® strap is the preferred construction, the invention contemplates the use of belt straps, buckle straps, stretch fit straps, or the like for securing the protective enclosure 1 to an object. The Velcro® strap 25 is to be used to secure the protective enclosure 1 to an object; whereby the fixed end 100 remains affixed to one clasp 24 and the removably secured end 102 is wrapped around the object, then fed through the opposite clasp 24, and finally removably secured to itself. The Velcro® strap 25 may tighten or loosen by means of the removably secured end 102.

FIG. 4 shows a cross-sectional view of first and second continuous edge portions, 14 and 20, respectively, about to sealingly mate as well as membrane periphery 60 mating with continuous channel 29. The front cover outer face 27 has at least one continuous channel 29 about the perimeter thereof; and the membrane 54 has a reciprocating periphery 60 to overlay the front cover 10. As shown, the periphery 60 overlays the channel 29 to from a removable mate. Also shown, is when the first continuous edge 14 is introduced to the second continuous edge groove 42. In the second continuous groove 42 is disposed a rubber seal 44 to resist water and moisture when the front cover 10 mates with the back cover 16. When the first continuous edge 14 is housed in the second continuous groove 42 they form a sealed mate.

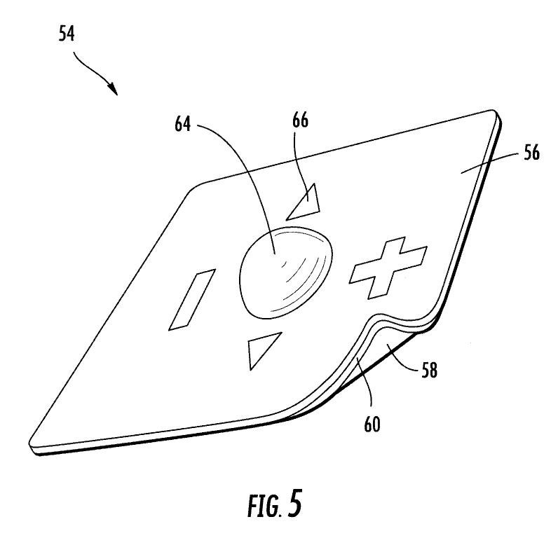

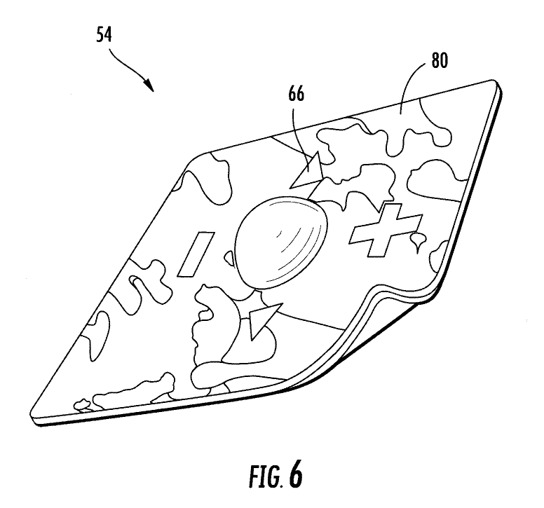

FIG. 5 shows a membrane 54. The membrane 54 is preferably constructed of silicone; however, other like materials will be suitable as well. The membrane 54 has a front side 56 and back side 58. The back side 58 has at least one continuous periphery 60 adapted to overlay the front cover outer face continuous channel 29. The continuous periphery 60 shown continues about the perimeter of the membrane backside 58 just offset from its edges. The membrane is adapted to overlay the front cover 10. The mating occurs when the membrane back side at least one continuous periphery 60 is inserted in the front cover outer face at least one continuous channel 29. The membrane front side 56 has indicia 66 imprinted thereon. Each indicia 66 corresponding to a particular electronic device's function key 70. The membrane front side 56 and backside 58 contains a central protrusion 64. The central protrusion 64 is defined as a convex surface or an indentation that projects outwardly on each side of the membrane 54. The membrane 54 back side central protrusion 64 is shown in FIG. 2. The back side pro central protrusion 64 falls into the front cover center opening 30, when the membrane 54 is overlaying the front cover 10 (shown in FIG. 2). Press down of the central protrusion 64 causes the corresponding electronic device's center function key 70 to activate. Exertion of a downward force on the indicia 66 on the membrane 54, located peripheral to the front side central protrusion 64, causes deflection on the corresponding independently sectioned flexible zone 28. Deflection of the independently sectioned flexible zone 28 causes the protrusion in association with each zone 28 to depress the electronic device's function key 70. Each protrusion 32 is in vertical alignment with a corresponding electronic device's function key 70. This precise alignment allows a user to exert a downward force anywhere about a particular indicia 66 on the membrane and cause a corresponding independently sectioned flexible zones 28 to deflect, whereby the precision of the alignment between the protrusion 32 and function key 70 will always return a resultant function. Additionally, FIG. 6 shows a decorative feature 80 which may be imprinted on a membrane 54.

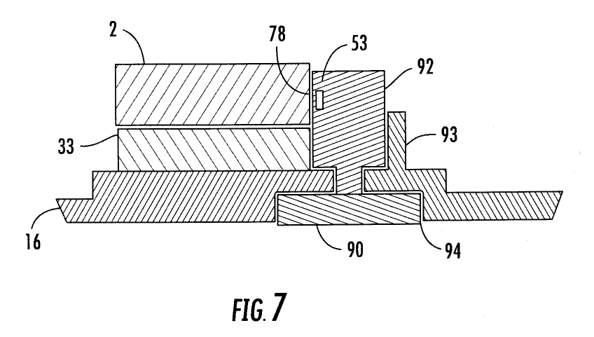

Optionally, a mechanical actuator mechanism 53 for activating the electronic device's ON/OFF switch 78 from outside the protective enclosure 1 may be constructed. As shown in FIG. 7 a cross sectional view from the hinge side of the protective enclosure, a mechanical actuator mechanism 53 consisting of: a thumb-switch 90, located on the back cover 16 within a housing 94, connected to a reciprocating member 92, a retaining wall 93 to hold reciprocating member 92 in place; and the reciprocating member 92 performing an analogous movement onto the electronic device's ON/OFF switch 78. Upon movement of the thumb-switch 90 the reciprocating member 92 performs the identical movement on the electronic device's ON/OFF switch 78. The thumb-switch 90 acts as an actuator of the electronic device's ON/OFF switch 73 from outside the protective enclosure 1. The thumb-switch 90 will slide about the small housing 94 within the back cover 16 in the same manner that the electronic device's slide switch does.

Furthermore, every electronic device's ON/OFF switch is activated in a different manner, such as a simple push button or slide switch; however, the preferred embodiment contemplates use of an IPod Shuffle® 2^{nd} generation which has a slide switch. Therefore the thumb-switch 90 will work as a slide switch, when working in conjunction with an IPod Shuffle® 2^{nd} generation. In an alternative embodiment, the thumb-switch 90 may work as a push button when used in conjunction with an electronic device having a push button. Also, on the IPod Shuffle® 2^{nd} generation the ON/OFF switch is located on the electronic device's sidewall, but on other electronic device the ON/OFF switch may be located on the back side, therefore it is contemplated that the thumb-switch on the protective enclosure may have to be disposed on the back cover sidewalls of the protective enclosure or the back cover may contain an opening on the back cover for actual activation of the ON/OFF switch on the electronic device itself.

All patents and publications mentioned in this specification are indicative of the levels of those skilled in the art to which the invention pertains. All patents and publications are herein incorporated by reference to the same extent as if each individual publication was specifically and individually indicated to be incorporated by reference.

It is to be understood that while a certain form of the invention is illustrated, it is not to be limited to the specific form or arrangement herein described and shown. It will be apparent to those skilled in the art that various changes may be made without departing from the scope of the invention and the invention is not to be considered limited to what is shown and described in the specification and any drawings/figures included herein.

One skilled in the art will readily appreciate that the present invention is well adapted to carry out the objectives and obtain the ends and advantages mentioned, as well as those inherent therein. The embodiments, methods, procedures and techniques described herein are presently representative of the preferred embodiments, are intended to be exemplary and are not intended as limitations on the scope. Changes therein and other uses will occur to those skilled in the art which are encompassed within the spirit of the invention and are defined by the scope of the appended claims. Although the invention has been described in connection with specific preferred embodiments, it should be understood that the invention as claimed should not be unduly limited to such specific embodiments. Indeed, various modifications of the described modes for carrying out the invention which are obvious to those skilled in the art are intended to be within the scope of the following claims.

What is claimed is:

1. A protective enclosure for an electronic device having an interactive generally flat panel control comprising:
a front cover including sidewalls, said front cover sidewalls further including a first continuous edge portion; a back cover including sidewalls, said back cover sidewalls further including a second continuous edge portion; said first continuous edge portion configured to sealingly mate said second continuous edge portion when said front cover is attached to said back cover defining an interior housing for enclosing said electronic device;
at least one pair of clasps attached to said protective enclosure;
said front cover having an outer face and inner face, said front cover further having center opening therethrough, said front cover including a plurality of independently sectioned flexible zones, each said independently sectioned flexible zone having a front surface area greater than the corresponding front surface area of a function key on said electronic device, each said independently sectioned flexible zone adapted to at least partially overlay said electronic device's function keys, each said independently sectioned flexible zone having protrusions on said front cover inner face, said protrusions associated with each said independently sectioned flexible zone in alignment with said electronic device's function keys, said front cover outer face having at least one continuous channel about the perimeter; and
an membrane, having front side and back side, said membrane back side including at least one continuous periphery adapted to overlay said channel on said front cover, said membrane front side having a plurality of indicia located thereon and each corresponding indicia to each said independently sectioned flexible zone, wherein exertion of a downward force on said indicia causes deflection of the corresponding said independently sectioned flexible zone, said associated protrusion, and said electronic device's function key.

2. A protective enclosure for an electronic device having an interactive generally flat panel control of claim 1, wherein said electronic device is an MP3 player.

3. A protective enclosure for an electronic device having an interactive generally flat panel control of claim 1, wherein said electronic device's function keys operate as pushbutton or touchpad.

4. A protective enclosure for an electronic device having an interactive generally flat panel control of claim 1, wherein said electronic device's function keys provide one or more functions selected from a group comprising of an increase in volume, decrease in volume, play, pause, fast forward, rewind, and stop.

5. A protective enclosure for an electronic device having an interactive generally flat panel control of claim 4, wherein said increase and decrease in volume are diametrically opposite about said electronic device.

6. A protective enclosure for an electronic device having an interactive generally flat panel control of claim 5, wherein said rewind and fast forward feature are diametrically opposite about said electronic device.

7. A protective enclosure for an electronic device having an interactive generally flat panel control of claim 1, wherein said plurality of said independently sectioned flexible zones is configured as four separate zones.

8. A protective enclosure for an electronic device having an interactive generally flat panel control of claim 7, wherein said independently sectioned flexible zones are formed by two slits orthogonally oriented with respect to each other.

9. A protective enclosure for an electronic device having an interactive generally flat panel control of claim 1, wherein said membrane is constructed of silicone.

10. A protective enclosure for an electronic device having an interactive generally flat panel control of claim 1, wherein said membrane is removably mounted and has decorative features.

11. A protective enclosure for an electronic device having an interactive generally flat panel control of claim 1, wherein said membrane and corresponding said independently sectioned flexible zones are flexible, so that upon exertion of a downward force on said membrane and deflection of said independently sectioned flexible zone they return to their original position.

12. A protective enclosure for an electronic device having an interactive generally flat panel control of claim 1, further including a securing mechanism that allows for engagement and disengagement of said enclosure to clothing, body parts, vehicle component, or other objects.

13. A protective enclosure for an electronic device having an interactive generally flat panel control of claim 12, wherein said securing mechanism is a hoop and loop fastener wherein one end removably secured about one said clasp and second end fixed about second said clasp.

14. A protective enclosure for an electronic device having an interactive generally flat panel control of claim 1, wherein said one sidewall of front cover and said one sidewall of back cover are connected by a hinge and pivot about said hinge.

15. A protective enclosure for an electronic device having an interactive generally flat panel control of claim 1, wherein said first continuous edge portion configured to sealingly mate said second continuous edge portion having a locking mechanism on said front cover sidewall, opposite said hinge, to securely lock said front cover to said back cover.

16. A protective enclosure for an electronic device having an interactive generally flat panel control of claim 15, wherein said locking mechanism includes at least one hinged member that operatively engages a latching member on said sidewall of said back cover.

17. A protective enclosure for an electronic device having an interactive generally flat panel control of claim 1, wherein at least one of said sidewalls has an aperture therein.

18. A protective enclosure for an electronic device having an interactive generally flat panel control of claim 17, wherein said aperture allows for entry of a plug-in component.

19. A protective enclosure for an electronic device having an interactive generally flat panel control of claim 18, wherein the cooperation of said aperture and said plug-in component are closely sized thereby resisting the entry of water and moisture into said interior housing.

20. A protective enclosure for an electronic device having an interactive generally flat panel control of claim 1, wherein said back cover is ergonomically configured to conform to the shape of an average arm.

21. A protective enclosure for an electronic device having an interactive generally flat panel control of claim 1, wherein said front cover and said back cover are constructed of a synthetic material.

22. A protective enclosure for an electronic device having an interactive generally flat panel control of claim 1, wherein said interior housing includes at least one holding member constructed to hold said electronic device in a fixed position within said interior housing.

23. A protective enclosure for an electronic device having an interactive generally flat panel control of claim 22, wherein said shape of electronic device is rectilinear.

24. A protective enclosure for an electronic device having an interactive generally flat panel control of claim 18, wherein said interior housing includes a cleat assembly capable of holding excess wire from said plug-in component.

25. A protective enclosure for an electronic device having an interactive generally flat panel control of claim 1, wherein said second continuous edge portion has a groove.

26. A protective enclosure for an electronic device having an interactive generally flat panel control of claim 25, wherein said second continuous edge portion groove has a seal positioned thereon to secure said sealingly mate of said front and back cover.

27. A protective enclosure for an electronic device having an interactive generally flat panel control of claim 1, wherein said seal capable of resisting water and moisture entry into said interior housing.

28. A protective enclosure for an electronic device having an interactive generally flat panel control of claim 1, wherein said membrane includes a central protrusion on said membrane front side and said membrane back side; and said membrane back side central protrusion falling within said front cover center opening and in alignment with said electronic device's function key wherein depression of the central protrusion causes depression of corresponding said electronic device's function key.

29. A protective enclosure for an electronic device having an interactive generally flat panel control of claim 1, wherein deflection anywhere about said greater front surface area of said independently sectioned flexible zone causes corresponding said electronic device's function key with said smaller front surface area to be activated.

30. A protective enclosure for an electronic device having an interactive generally flat panel control of claim 1, wherein exertion of a downward force on said membrane anywhere about said indicia overlaying said independently sectioned flexible zone causes corresponding said electronic device's function key with said smaller front surface area to be activated.
